(19) United States
(12) Patent Application Publication
(10) Pub. No.: US 2016/0164279 A1
(43) Pub. Date: Jun. 9, 2016

(54) CIRCUIT AND METHOD FOR MEASURING A CURRENT

(71) Applicant: Infineon Technologies AG, Neubiberg (DE)

(72) Inventors: Michael Asam, Sainbach (DE); Andreas Meiser, Sauerlach (DE); Steffen Thiele, Muenchen (DE)

(21) Appl. No.: 14/564,172

(22) Filed: Dec. 9, 2014

(51) Int. Cl. H02H 9/02; G01R 19/165; H03K 19/0185

(52) U.S. Cl. CPC H02H 9/025; H03K 19/018507; G01R 19/16519; G01R 19/16538

(57) ABSTRACT

Circuits, switches with over-current protection and methods for measuring a current are described herein. A circuit configured to provide a current from a supply voltage to a load includes a first transistor, a second transistor, and a detecting circuit. The first transistor has a larger active area than the second transistor. The detecting circuit is configured to detect a current through the second transistor. A same voltage is applied between a control terminal of the first transistor and a first controlled terminal of the first transistor and is applied between a control terminal of the second transistor and a first controlled terminal of the second transistor. The detecting circuit is coupled to the second controlled terminal of the second transistor and is coupled to the supply voltage.

### TECHNICAL FIELD

Various embodiments relate generally to circuits, switches with over-current protection and methods for measuring a current through a power transistor.

### BACKGROUND

Currents flowing through switching devices may need to be measured via a circuit, for example to detect over-currents or short circuits. The circuit should be able to detect a first type of short circuit, in which the short circuit is present before the switching device is activated. It should also be able to detect a second type of short circuit, in which the short circuit occurs while the switching device is conducting. Preferably, the circuit should be accurate, be robust over temperature variations and device variations, have low chip area requirements, and have a low power consumption.

### SUMMARY

According to one embodiment, a circuit configured to provide a current from a supply voltage to a load is described herein. The circuit includes a first transistor, a second transistor, and a detecting circuit. The first transistor has a larger active area than the second transistor. The detecting circuit is configured to detect a current through the second transistor. A same voltage is applied between a control terminal of the first transistor and a first controlled terminal of the first transistor and is applied between a control terminal of the second transistor and a first controlled terminal of the second transistor. The detecting circuit is coupled to the second controlled terminal of the second transistor and is coupled to the supply voltage.

According to another embodiment, a switch with over-current protection is described herein. The switch includes a power transistor, a sense transistor, a sense resistor and an over-current detection circuit. The power transistor and the sense transistor are integrated on a common substrate as source-down transistors with respective drains. The sense resistor is coupled to a drain terminal of the sense transistor. The over-current detection circuit is configured to detect a voltage drop across the sense resistor.

Further, according to another embodiment, a method for measuring a current, for example through a power transistor configured to provide a current from a supply voltage to a load, is described. The method includes coupling a sense transistor in parallel to the power transistor, applying a same control signal to the sense transistor and to the power transistor; and detecting a current through the sense transistor. The same control signal is configured to control a current flow through the sense transistor and to control a current flow through the power transistor.

### BRIEF DESCRIPTION OF THE DRAWINGS

In the drawings, like reference characters generally refer to the same parts throughout the different views. The drawings are not necessarily to scale, emphasis instead generally being placed upon illustrating the principles disclosed. In the drawings, the left-most digit(s) of a reference number may identify the drawing in which the reference number first appears. The same numbers may be used throughout the drawings to reference like features and components.

In the following description, various embodiments are described with reference to the following drawings, in which:

FIG. 1 shows an embodiment of a circuit;

FIG. 2 shows an embodiment of a semiconductor device;

FIG. 3 shows an embodiment of a circuit with a regulator circuit;

FIG. 4 shows an embodiment of another circuit;

FIG. 5 shows an embodiment of a circuit with IGBT;

FIG. 6 shows an embodiment of a circuit with low side switches;

FIG. 7 shows an embodiment of another circuit;

FIG. 8 shows an embodiment of another circuit with P-channel switches;

FIG. 9 shows an embodiment of another circuit;

FIG. 10 shows an embodiment of another circuit;

FIG. 11 shows an embodiment of a circuit with two different supply voltages;

FIG. 12 shows embodiments of another circuit; and

FIG. 13 shows an embodiment of a method.

### DETAILED DESCRIPTION

The following detailed description refers to the accompanying drawings that show, by way of illustration, specific details and embodiments in which the embodiments may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

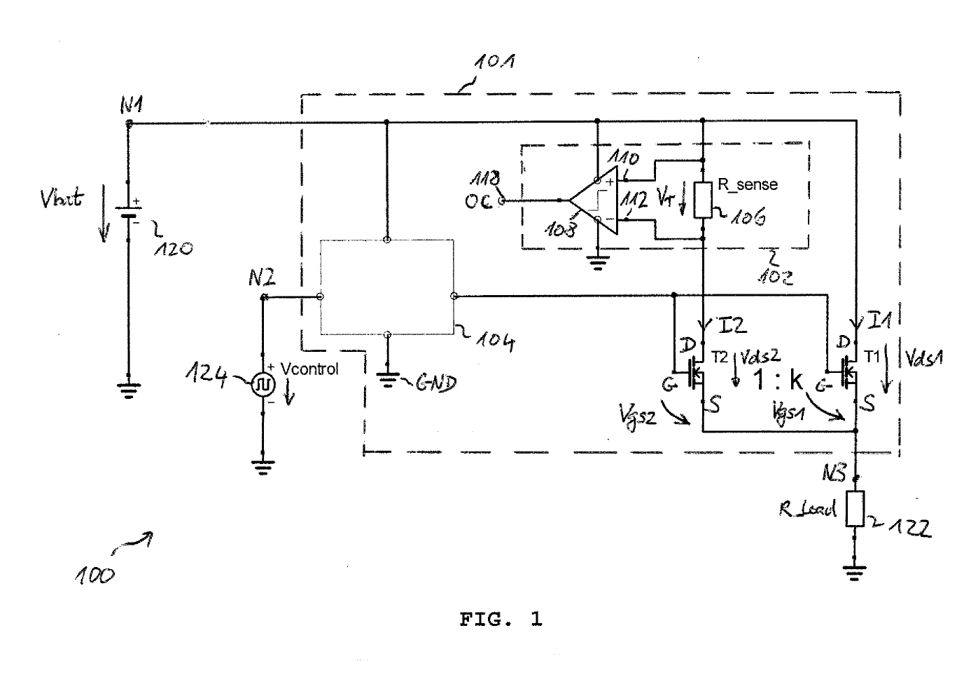

FIG. 1 shows an embodiment 100 of a circuit 101. The circuit 101 may have an input (or a node) N1, another input (or a node N2), and an output (or a node N3). It may further be coupled to a first reference potential GND, such as a ground potential.

A power supply, such as a battery 120 or voltage source, may be coupled to input N1. The battery 120 or voltage source may have a voltage Vbat. A signal source 124 may be coupled to input N2. The signal source 124 may provide a signal Vcontrol, for example a pulse-width modulated signal. Signal Vcontrol may be a digital signal with a varying duty cycle. A load 122 may be coupled to the output N3. It may be a resistor with a resistance R_load, an electric motor, a lamp or any other electric load.

The circuit 101 may be a switch, for example a power switch, with current detection. Current detection may include measuring a current or comparing a current to a threshold, for example to detect an over-current. The circuit may be used for switching power sources, inverter devices, or the like. For example, depending on signal Vcontrol, it may switch a power supply, such as battery 120, to supply the load 122 with an adjustable power.

The circuit 101 may include a first transistor T1, a second transistor T2, a detecting circuit 102 and a charge pump 104.

The first transistor T1 and the second transistor T2 may, for example, switch high voltages. The first transistor T1 may have a larger active area than the second transistor T2. That is, it may have a ratio W1/L1 of its gate width W1 to its gate length L1 that is larger, for example by factor k, than a ratio W2/L2 of the gate width W2 to the gate length L2 of the second transistor T2. If the first transistor T1 and the second transistor T2 are biased the same way, a current I2 flowing through the second transistor T2 may be smaller by a factor k than the current I1 flowing through the first transistor T1. The smaller current I2 may be measured and current I1 may be determined by: I2=I1/k. To reduce current I2, it may be desired to have large values of k, for example in the range of 100 to 10,000, or 500 to 2,000, or about 1,000.

The first transistor T1 may be a power switching element, for example a power transistor, for example a power Metal Oxide Semiconductor Field Effect Transistor (MOSFET). It may switch high voltages with very small switching and conduction losses. It may be a single transistor or it may be made up of a number of transistors connected in parallel to each other. The number of parallel connected transistors may be k. The second transistor may be a sense transistor. It may be a transistor like one of the transistors of the first transistor connected in parallel to each other.

In various embodiments, a control terminal G, for example a gate, of the first transistor T1 and a control terminal G, for example a gate, of the second transistor T2 may be coupled, for example directly electrically connected, together. The control terminal G of the first transistor T1 may have the same potential as the control terminal G of the second transistor T2.

In various embodiments, a first controlled terminal S of the first transistor T1 may be coupled, for example directly electrically connected, to a first controlled terminal S of the second transistor T2. The first controlled terminal S of the first transistor T1 may have the same potential as the first controlled terminal S of the second transistor T2.

In various embodiments, a second controlled terminal D of the first transistor T1 and a second controlled terminal D of the second transistor T2 may be coupled to a same supply potential, for example the potential at node N1, for example to the potential Vbat. In various embodiments, the second controlled terminal D of the first transistor T1 and the second controlled terminal D of the second transistor T2 are not directly electrically connected to each other. The second controlled terminal D of the first transistor T1 may be directly connected to node N1 and the second controlled terminal D of the second transistor T2 may be coupled via detecting circuit 102 to node N1.

A signal configured to control a conductivity between the first controlled terminal S and a second controlled terminal D of the first transistor T1 and of the second transistor T2 may be coupled between the control terminal G of the first transistor T1 and the first controlled terminal S of the first transistor T1 and may be coupled between the control terminal G of the second transistor T2 and the first controlled terminal S of the second transistor T2.

In various embodiments, the first transistor T1 and the second transistor T2 may, for example, be MOSFETS. The control terminals may be gate terminals G, the first controlled terminals may be a source terminals S, and the second controlled terminals may be drain terminals D.

In various embodiments, the gate G of the power transistor T1 and the gate G of the sense transistor T2 are coupled together. The signal configured to control the conductivity between the first controlled terminals S and the second controlled terminals D may be a voltage Vgs1, Vgs2 between the respective gate terminal G and the respective source terminal S of the first transistor T1 and the second transistor T2.

In various embodiments, the first transistor T1 and the second transistor T2 may both be N-channel devices. The first transistor T1 and the second transistor T2 may be configured as a high-side switches. High-side switches may be coupled to a potential that is higher than the potential that the load is coupled to. In other words, they may be coupled between a supply potential, for example Vbat, and the load 122, which is coupled to a first reference potential GND, for example a ground potential.

When the first transistor T1 and the second transistor T2 are non-conducting, the potential of the sources S may be at (or near) the supply potential, for example Vbat. A level shifter 104, for example a DC-to-DC converter or a charge pump, may be necessary to convert signal Vcontrol to a voltage level higher than the supply potential (for example Vbat). The level shifter 104 may be powered by a voltage between the supply potential Vbat and the first reference potential GND. It may provide a voltage level higher than the supply potential to the control terminals G of the first transistor and the second transistor T2. The signal configured to control the conductivity between the respective first controlled terminal S and the respective second controlled terminal D, for example Vgs1, Vgs2, may then render the first transistor T1 and the second transistor T2 conductive. In some embodiments, the charge pump 104 may be optional.

The detecting circuit 102, for example an over-current detection circuit, may be configured to detect a current I2 through the second transistor T2. It may be coupled to the second controlled terminal D, for example the drain, of the second transistor T2.

In various embodiments, the detecting circuit 102 may include a resistor 106, for example a sense resistor, coupled in series to the second transistor T2. The resistor 106 may be coupled between the supply potential, for example Vbat, and the second controlled terminal (or drain) D of the second (or sense) transistor T2. The detecting circuit 102 may be configured to detect a voltage drop Vr across the resistor 106. The current through the second transistor T2 may be given by I2=Vr/R_sense.

The resistor 106 may be a polysilicon or a metal resistor. It may a portion of or formed along a drain electrode, for example of the drain metallization, of the second transistor T2. It may be a bond wire. The resistor 106 may calibrated, for example using laser fuses, to increase the accuracy of the current detection. It may have a positive temperature dependence, that is, its resistance may increase with temperature. At high temperatures, the positive temperature dependence may reduce the short circuit current threshold, that is, the amount of current needed to trigger an over-current signal.

In some cases, it may be sufficient to know if an over-current has occurred. For this, the voltage Vr representing the current I2 may be compared to a threshold. In various embodiments, the detecting circuit 102 may include a comparator 108 coupled across the resistor 106, for example by coupling a first input 110 of the comparator 108 across one terminal of the resistor 106 and coupling a second input 112 of the comparator 108 across the other terminal of the resistor 106. The comparator 108 may be powered by the supply potential, for example Vbat.

The detecting circuit 102 may output a digital signal OC, for example a “0” and a “1”, at an output 118 of the comparator 108. A “0” may indicate that the current I2 is lower than a current threshold and that there is no over-current. A “1” may indicate that the current I2 is higher than the current threshold and that there is an over-current. However, instead of a digital signal, embodiments of the detecting circuit 102 may output an analog, that is a continuous or proportional, signal OC that allows a measurement of the current I2 flowing. The signal OC may be processed inside the circuit, for example by parts not shown for reasons of clarity, or may be passed to a terminal and processed outside.

The signal controlling the respective conductivity between the respective first controlled terminal S and the respective second controlled terminal D, for example, the gate-source voltages Vgs1, Vgs2, may be the same, that is Vgs1=Vgs2, for both transistors T1, T2. The signal may be unaffected by the detecting circuit 102 as the voltage drop Vr across the resistor 106 occurs at one side of the second transistor T2, that is, the side of the second controlled terminal D or drain side and controlling the conductivity takes place at another side of the second transistor T2, that is the side of the first controlled terminal S or source side.

If the resistor 106 of the detecting circuit 102 would be arranged on the side of the first controlled terminal S or the source side of the second transistor T2, a current I2 flowing through the transistor T2 will produce a voltage drop Vr that may change the signal controlling the conductivity between the first controlled terminal S and the second controlled terminal D. In other words, the signal Vgs1, Vgs2 may differ for the first transistor T1 and the second transistor T2, that is Vgs1 Vgs2, which may cause an inaccurate current detection.

For the first type of short circuit, in which the short circuit is present before the switching device T1 is activated, the voltages Vds1 and Vds2 between the respective first and the respective second controlled terminals S and D may be very large and may be equal or nearly equal to the supply voltage Vbat. The voltage drop Vr across the resistor 106 may be neglected as the second transistor T2 may operate in saturation mode where a change in the voltage Vds only has a small influence on the current Ids. The current I2 through the second transistor T2 may therefore be independent or nearly independent from the voltage drop Vr along the resistor 106, allowing an accurate detection of current I2.

For the second type of short circuit, in which the short circuit occurs while the switching device is conducting, the voltages Vds1 and Vds2 between the first and the second controlled terminals S and D may be very small and may be equal or nearly equal to zero. However, the voltage drop Vr across the resistor 106 has no influence on the signal Vgs1, Vgs2 controlling the conductivity.

The detection circuit 102, for example the comparator 108 of the detection circuit 102, may be powered by the supply potential, for example the potential at node N1, for example Vbat. It does not need to be powered by the level shifter 104 which may reduce the power consumption of the circuit 101 as the charge pump 104 may have a poor efficiency.

If the load 122 is inductive, or due to inductances in the wiring to the load 122, turning the first transistor T1 off may cause node N3 to have a negative potential with respect to the ground potential GND. If the detection circuit 102 is coupled to node N3 (or the first controlled terminals S or sources), for example to power the detection circuit 102, the detection circuit 102 may need to be designed to cope with negative voltages. This may require special circuits with complicated layouts for the detection circuit 102, which may lead to greater chip area, a greater interference sensitivity at high slew rates, and lower inverse current capability. However, if the detection circuit 102 is powered by the supply voltage, for example Vbat, it is not powered by a floating potential such as the potential of node N3 (or of the first controlled terminals S). It does not need to be designed for negative potentials, which may simply its design and may lead to smaller and more robust detection circuits 102.

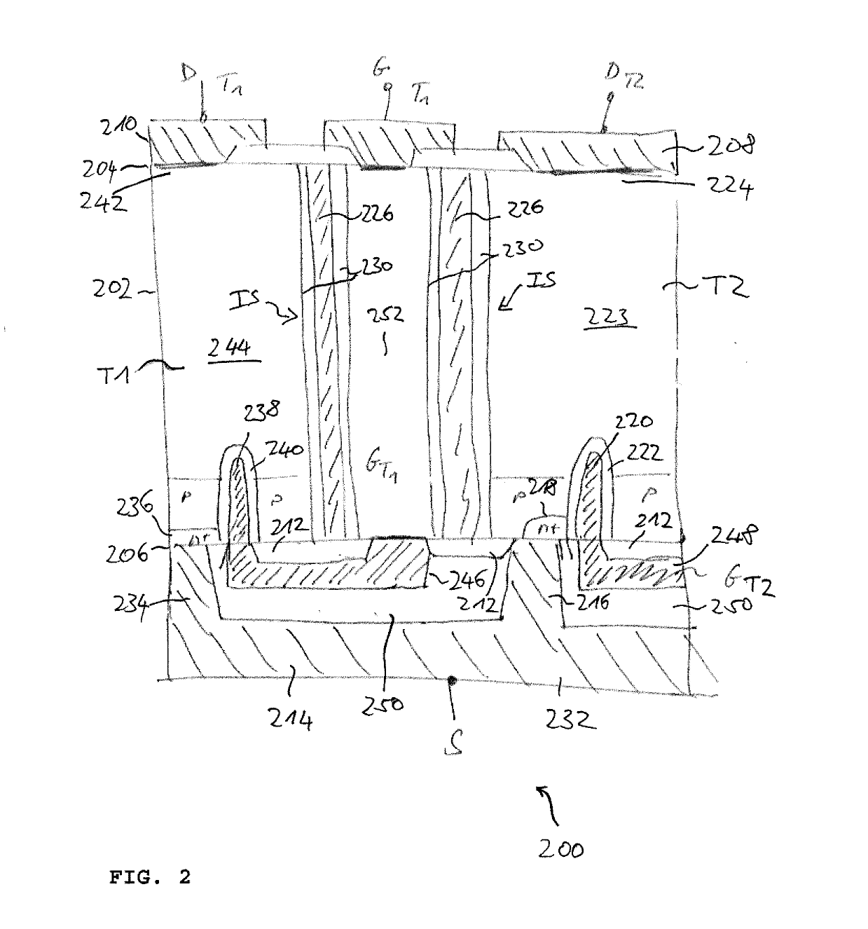

FIG. 2 shows an embodiment 200 of a semiconductor device. To increase current and breakdown voltage rating, switching devices, such as power switching devices, may be constructed “vertically”, that is, the source electrode and the drain electrode may be placed so that current flows vertically with respect to the wafer plane between the electrodes. A vertical power MOSFET may have its source terminal and its gate terminal on the first side of a semiconductor substrate and its drain terminal on the opposite side of the semiconductor substrate, or on its second side. The first side may be the top side or front side, that is, the side where active devices are typically processed and formed on. The second side may be the bottom side or back side of the wafer. However, the monolithic integration of such power MOSFETs may be restricted to applications having a common drain connection.

A “source down” or “source-substrate connection” device, such as for example a vertical structure transistor, may have a drain and a gate terminal arranged on a first side of a semiconductor substrate while a source terminal is arranged on a second side of the semiconductor substrate that lays opposite to the first side. Since the source is at the back side of the chip, no isolation between a lead frame and ground is required, which may simplify cooling of the semiconductor device.

The embodiment 200 may be a source down semiconductor device. It may have a first transistor T1 and a second transistor T2. The first transistor T1 and the second transistor T2 may be electrically isolated from each other by insulation structures IS. The semiconductor device may include a semiconductor substrate 202. The semiconductor substrate 202 may include a first main surface 204 and a second main surface 206. Insulation layers 212 may be arranged on parts of the first main surface 204 and of the second main surface 206.

Transistor T1 may include a source region 236, a drain region 242, a gate electrode 238 and a drift region 244. The source region 236 may be disposed adjacent to the second main surface 206. The source region 236 may be connected to a source electrode 232 by means of a source contact 234. The drain region 242 may be disposed adjacent to the first main surface 204. The drain region 242 may be connected to a drain electrode 210. The gate electrode 238 may be disposed in a trench formed in the second main surface 206. The gate electrode 238 may be insulated from the adjacent semiconductor material by means of a gate dielectric layer 240. When a suitable voltage is applied to the gate electrode 238, a conductive channel is formed in the body region adjacent of the gate electrode 238, resulting in a current flow between the source region 236 and the drain region 242 via the conductive channel and the drift region 244.

Transistor T2 may include a source region 218, a drain region 224, a gate electrode 220 and a drift region 223. The source region 218 may be disposed adjacent to the second main surface 206. The source region 218 may be connected to a source electrode 214 by means of a source contact 216. The drain region 224 may be disposed adjacent to the first main surface 204. The drain region 224 may be connected to a drain electrode 208. The gate electrode 220 may be disposed in a trench formed in the second main surface 206. The gate electrode 220 may be insulated from the adjacent semiconductor material by means of a gate dielectric layer 222. When a suitable voltage is applied to the gate electrode 220, a conductive channel is formed in the body region adjacent of the gate electrode 220, resulting in a current flow between the source region 218 and the drain region 224 via the conductive channel and the drift region 223.

The metallization of the source electrodes 214, 232 may be disposed adjacent to the second main surface 206, for example on the insulation layer 212. The metallization of the drain electrodes 208, 210 may be disposed adjacent to or on the first main surface 204. The gate electrodes 220, 238 may be connected via connection portions 246, 248 that may be formed on the isolation layer 212. The connection portions 246, 248 may be insulated from the source electrodes 214, 232 by further isolation layers 250. The connection portions 246, 248 may be contacted by an electrically conducting material 252 that extends between the first main surface 204 and the second main surface 206. The electrically conducting material 252 may be isolated from other parts by isolating structures IS on either side of it. It may be connected to a gate terminal G on the first main side 204. FIG. 2 shows the electrically conducting material 252 and the isolating structures IS only for the gate of transistor T1, however, they may be provided in a similar manner for the transistor T2.

The insulation structure IS may extend from the first main surface 204 to the second main surface 206. It may be filled with conductive material 226, for example to increase mechanical stability. The conductive material 226 may be isolated from the adjacent substrate portion by means of an insulating layer 230.

In various embodiments, the first transistor (or power transistor) T1 and the second transistor (or sense transistor) T2 may be integrated or manufactured on a same (or common) substrate 202. The manufacturing of the first transistor T1 and the second transistor T2 on the same (or common) substrate 202 may reduce the effects of processing variations, material variations and temperature variations on the factor k and allow a more accurate current detection.

In various embodiments, the first transistor T1 and the second transistor T2 share a common electrode, for example a common source electrode. For example, the source electrode 232 of the first transistor T1 and the source electrode 214 of the second transistor T2 may be electrically connected to each other. The source electrodes 214, 232 may be formed as one electrode in the metallization. However, in some embodiments, the source electrodes 214, 232 may be separate from each other and may have separate metallizations. The source of the power transistor T1 and the source of the sense transistor T2 may have the same electric potential.

In various embodiments, the first transistor T1 and the second transistor T2 may be source-down (or “first controlled terminal”-down) transistors with respective drains. In other words, the drain (or second controlled terminal) of the power transistor T1 is not directly electrically connected to the drain (or second controlled terminal) of the sense transistor T2. The first transistor T1 and the second transistor T2 may have separate drain electrodes 210, 208. The drain electrodes 210, 208 may be electrically isolated from each other. Therefore, the monolithic integration of the first transistor T1 and the second transistor T2 is not restricted to applications having a common drain (or a common second controlled terminal) connection. A detection circuit 102 may be coupled to the drain (or second controlled terminal) D of the sense transistor T2 without changing the signal, for example the gate-source voltages Vgs1, Vgs2, controlling the conductivity between the first controlled terminals S and the second controlled terminals D.

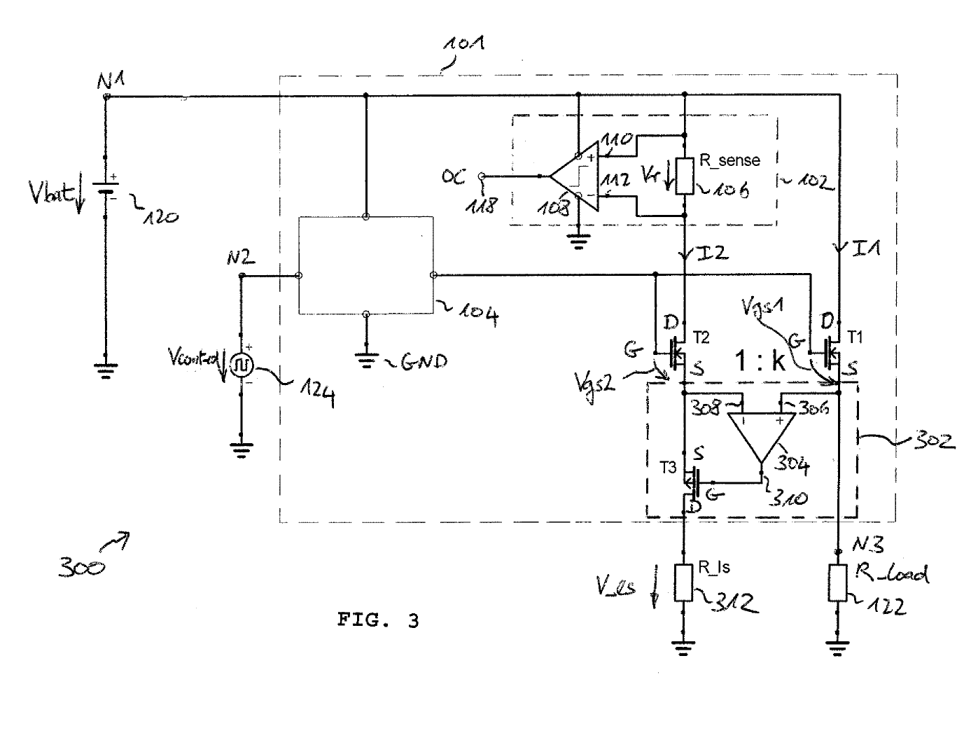

FIG. 3 shows an embodiment 300 of a circuit, which may be similar to the circuit described in conjunction with FIG. 1, so that the same features may apply to both circuits. In contrast to the circuit shown in FIG. 1, the first controlled terminal S of the first transistor T1 and the first controlled terminal S of the second transistor T2 of the circuit shown in FIG. 2 are not directly electrically connected to each other. Instead, embodiment 300 may include a regulator circuit 302 coupled to the first controlled terminals S of the first transistor T1 and the first controlled terminal S of the second transistor T2. The regulator circuit 302 may be configured to apply a same potential to the first controlled terminal (or source) S of the first transistor T1 and to the first controlled terminal (or source) S of the second transistor T2. In this way, the source S of the power transistor T1 and the source S of the sense transistor T2 may be configured to be at the same electric potential. The signal, for example the voltages Vgs1, Vgs2, which is configured to control the respective conductivity between the respective first controlled terminal S and the respective second controlled terminal D of the first and the second transistor T1, T2, may be the same for both transistors T1, T2 if the control terminals (or gates) of the transistors T1, T2 are also supplied with a same potential.

In various embodiments, the regulator circuit 302 may include an operational amplifier 304 and a third transistor T3. An input of the operational amplifier 304 may be coupled between the first controlled terminal S of the first transistor T1 and the first controlled terminal S of the second transistor T2. For example, a first input 306, for example a positive input, of the operational amplifier 304 may be coupled to the first controlled terminal (or source) S of the first (or power) transistor T1. A second input 308, for example a negative input, of the operational amplifier 304 may be coupled to the first controlled terminal (or source) S of the second (or sense) transistor T2. The third transistor T3 may be a P-channel transistor. A first controlled terminal S, for example a source, of the third transistor T3 may be coupled to the first controlled terminal S of the second transistor T2. A second controlled terminal D, for example a drain, of the third transistor T3 may be coupled to one end of a resistor 312. The other end the resistor 312 may be connected to a first reference potential GND, for example a ground potential. The resistor 312 may have a resistance R_Is and may provide a path for current I2 through the second transistor T2. The resistor 312 may be used to provide an analog voltage V_Is which is proportional to current I2. An output 310 of the operational amplifier 304 may be coupled to a control terminal G of the third transistor T3.

If the voltage (or potential difference) between the first controlled terminal S of the first transistor T1 and the first controlled terminal S of the second transistor T2 is positive, the operational amplifier 304 may increase the signal at its output 310. The signal may cause the third transistor T3 to conduct less which may lead to a rise in the potential of the first controlled terminal S of the second transistor T2. The potential of the first controlled terminal S of the second transistor T2 may increase until it exceeds the potential of the first controlled terminal S of the first transistor T1. If the voltage between the first controlled terminal S of the first transistor T1 and the first controlled terminal S of the second transistor T2 is negative, the operational amplifier 304 may decrease the signal at its output 310. The signal may cause the third transistor T3 to conduct more which may reduce the potential of the first controlled terminal S of the second transistor T2. Thus, the regulator circuit 302 controls the third transistor T3 so that the first controlled terminals S of the first and second transistor T1, T2 are at the same potential.

The embodiment shown in FIG. 3 may provide an internal, for example digital, over-current signal OC as well as an external, for example analog, voltage signal V Is at the resistor 312 that is proportional to the current I2.

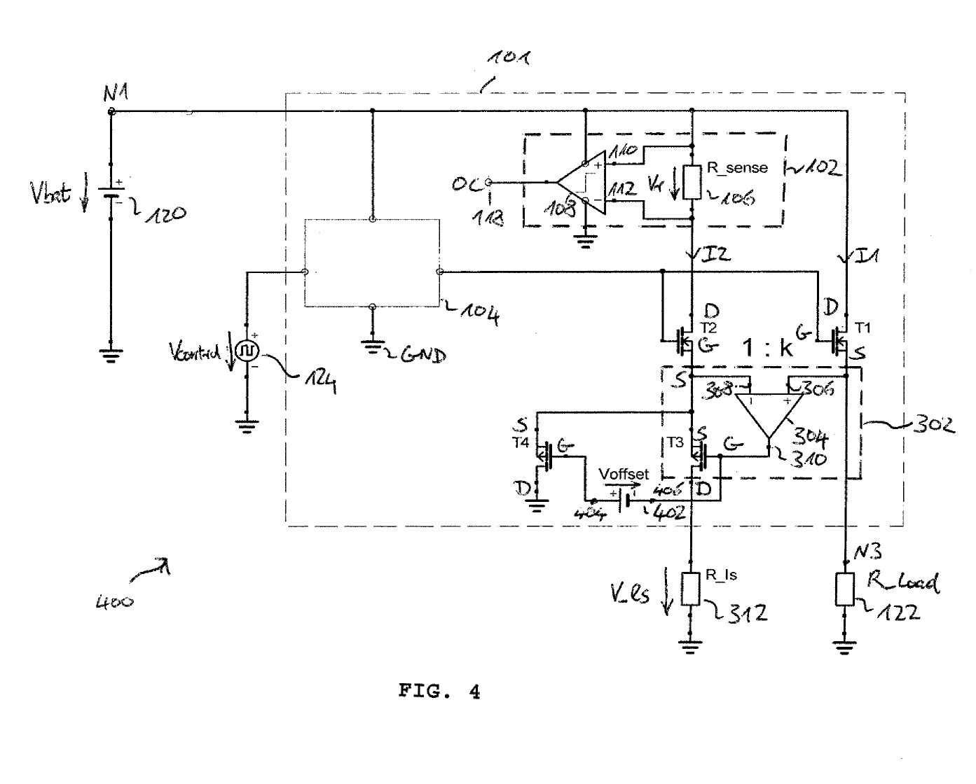

FIG. 4 shows an embodiment 400 of a circuit, which may be similar to the circuit described in conjunction with FIG. 3, so that the features described in conjunction with FIG. 3 may also apply to the circuit in FIG. 4. In contrast to the circuit shown in FIG. 3, the circuit may further include a fourth transistor T4 and a level shifter 402.

A first controlled terminal S, for example a source, of the fourth transistor T4 may be coupled to the first controlled terminal S of the third transistor T3. A second controlled terminal D, for example a drain, of the fourth transistor T4 may be coupled to the first reference potential GND, for example a ground potential. The fourth transistor T4 may be a P-channel transistor.

A first terminal 404, for example a positive terminal, of the level shifter 402 may be coupled to a control terminal G of the fourth transistor T4. A second terminal 406, for example a positive terminal, of the level shifter 402 may be coupled to the control terminal G of the third transistor T3. The level shifter 402 may provide a potential difference or a voltage Voffset between its first terminal 404 and its second terminal 406. It may increase the potential at the control terminal G of the fourth transistor T4 to be higher by Voffset than the potential at the control terminal G of the third transistor T3.

If resistor 312 is present, current I2 may flow through the third transistor T3 and the resistor 312. The potential at the first controlled terminal S of the fourth transistor T4 may be lower than the potential at the control terminal G of the fourth transistor T4. The fourth transistor T4 may therefore be off and no current flows through it.

Resistor 312 may be removed if it is not desired to evaluate the current I2 external to the circuit 101 using the voltage drop at the resistor 312. No current flows through the third transistor T3. The potential at the first controlled terminal S of the fourth transistor T4 may be higher than the potential at the control terminal G of the fourth transistor T4. The fourth transistor T4 may therefore be on and current I2 may flow through it. The detecting circuit 102 may therefore continue to provide a current measurement signal or an over-current signal OC without the resistor 312.

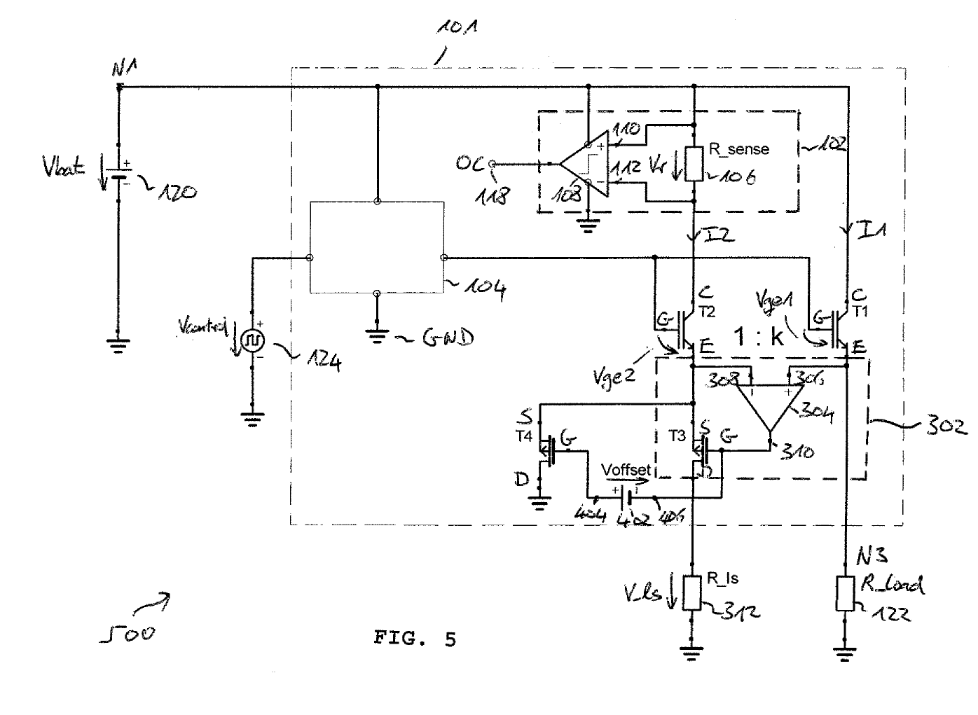

FIG. 5 shows an embodiment 500 of a circuit, which may be similar to the circuit described in conjunction with FIG. 4, so that the features described in conjunction with FIG. 4 may also apply to the circuit in FIG. 5. In contrast to the circuit shown in FIG. 4, the first transistor T1 and the second transistor T2 may be insulated gate bipolar transistors (IGBT) instead of MOSFETs. IGBTs may combine the isolated gate-drive characteristics of a

MOSFETs with the high-current and low-saturation-voltage capability of a bipolar transistor in a single device. The control terminals may be gate terminals G, the first controlled terminals may be emitter terminals E, and the second controlled terminals may be collector terminals C. The first transistor T1 and the second transistor T2 may be N-channel IGBTs. The signal configured to control the respective conductivity between the respective first controlled terminal E and the respective second controlled terminal C may be the respective voltage Vge1, Vge2 between the respective gate terminal G and the respective emitter terminal E.

In various embodiments, the first transistor T1 and the second transistor T2 may be emitter-down vertical IGBTs. In common vertical IGBTs, the emitter terminal E and the G gate terminal may be on the top side of a semiconductor substrate and the collector terminal C may be on the opposite side of the semiconductor substrate, that is, on its back side. However, the monolithic integration of such IGBTs may be restricted to applications having a common collector connection. A “emitter-down” or “emitter-substrate connection”-IGBT may have a collector C and a gate terminal G arranged on a first side of a semiconductor substrate while the emitter terminal E is arranged on a second side of the semiconductor substrate that lays opposite to the first side. The first side may be the top side or front side, that is, the side where active devices are typically formed on. The second side may be the bottom side or back side of the wafer. The first IGBT T1 and the second IGBT T2 may share a common substrate. They may be processed or manufactured together, that is, using the same semiconductor processing steps and materials. They may have separate, that is electrically isolated, emitters E.

A detection circuit 102 may be coupled to the collector (or second controlled terminal) C of the sense transistor T2 without changing the signal, for example the gate-emitter voltages Vge1, Vge2, controlling the conductivity between the first controlled terminals E and the second controlled terminals C.

The first transistor T1 and the second transistor T2 may be N-channel IGBTs. However, embodiments with P-channel IGBT are also possible.

In other embodiments of the circuit described in other figures herein, the MOSFETs used for the first transistor T1 and the second transistor T2 may also be replaced with IGBTs.

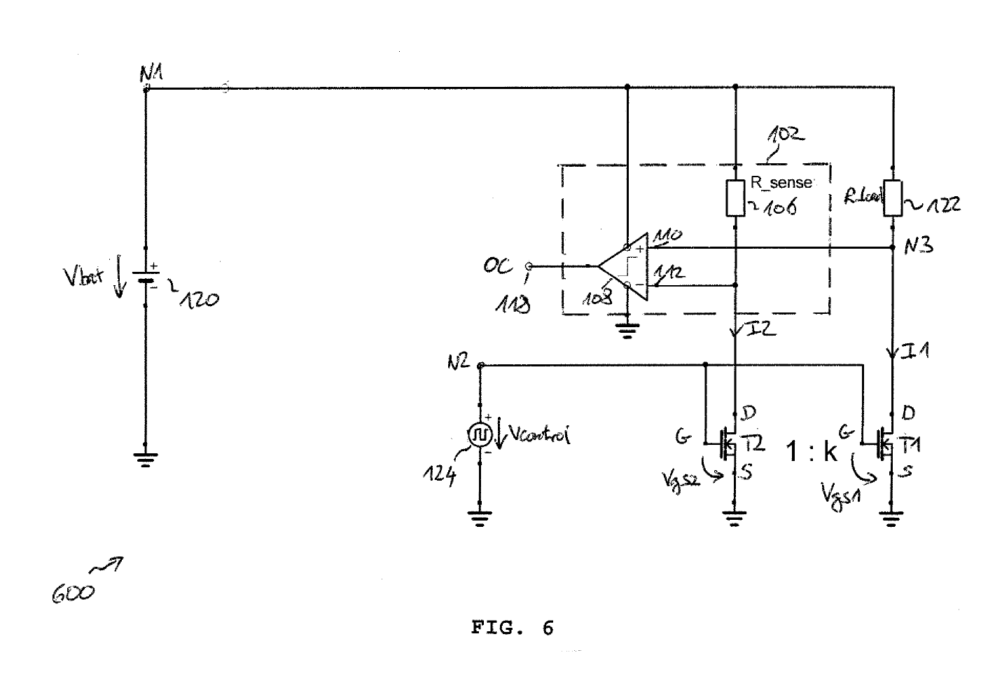

FIG. 6 shows an embodiment 600 of a circuit, which may be similar to the circuit described in conjunction with FIG. 1, so that the features described in conjunction with FIG. 1 may also apply to the circuit in FIG. 6.

In contrast to the circuit shown in FIG. 1, where the first transistor T1 and the second transistor T2 are configured as a high-side switches, the first transistor T1 and the second transistor T2 of FIG. 6 may be configured as a low-side switches. Low-side switches may be coupled to a lower potential than the potential that the load 122 is coupled to, or, in other words, the load 122 may be coupled to higher potential than the switches. For example, the first controlled terminals (for example sources) S of the first transistor T1 and of the second transistor T2 may both be coupled to the first reference potential GND, for example to a ground potential. One terminal of the load 122 may be coupled to the supply potential, for example Vbat. The other terminal of the load 122 may be coupled to the second controlled terminal (for example drain) D of the first transistor T1.

A level shifter 104, for example a charge pump, as shown in the embodiment of FIG. 1 may not be necessary for the circuit shown in FIG. 6 to control the respective conductivity between the respective first controlled terminal S and the respective second controlled terminal D. Signal Vcontrol may be coupled to the gates and needs not be raised to a level higher than the supply potential Vbat. A positive voltage Vgs1, Vgs2 smaller than Vbat may render the N-channel first transistor T1 and the second transistor T2 conducting.

In contrast to the circuit shown in FIG. 1, where the comparator 108 is coupled across the resistor 106, the first input 110 of the comparator 108, for example a positive input, is coupled to the terminal of the load 122 that is not coupled to the supply potential (for example Vbat). A second input 112 of the comparator 108, for example a negative input, may remain coupled to the terminal of the resistor 106 that is not coupled to the supply potential (for example Vbat). The potential difference between the first input 110 and the second input 112 may be given by I1·R_load-I2·R_sense. It may be positive if current I1 is larger than a certain value of current I2 and may be negative if current I1 is smaller than the certain value of current I2.

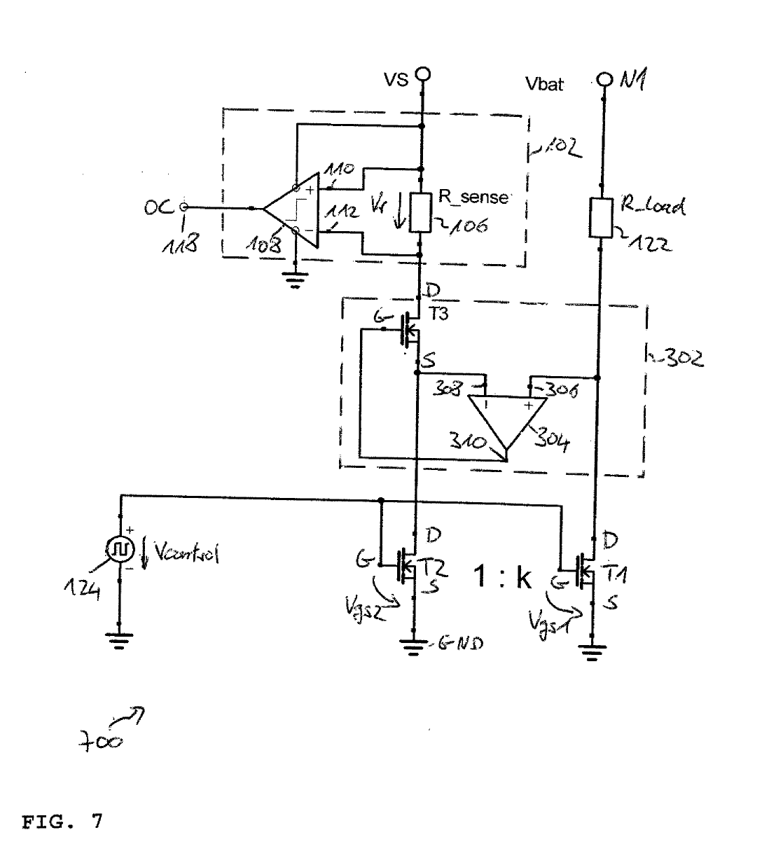

FIG. 7 shows an embodiment 700 of a circuit, which may be similar to the circuit described in conjunction with FIG. 3, so that the features described in conjunction with FIG. 3 may also apply to the circuit in FIG. 7.

In contrast to the circuit shown in FIG. 3, where the first transistor T1 and the second transistor T2 are configured as a high-side switches, the first transistor (or power transistor) T1 and the second transistor (or sense transistor) T2 may be configured as a low-side switches. The first controlled terminals (for example sources) S of the first transistor T1 and of the second transistor T2 may both be coupled to the first reference potential GND, for example to a ground potential. The load 122 may be coupled between a first supply potential, for example Vbat, and the second controlled terminal (for example drain) D of the first transistor T1. The second controlled terminal D of the second transistor T2 may be coupled to a second supply potential VS. The first supply potential Vbat and the second supply potential VS may be different from each other. In other words, the sensing path and the load path may be powered by different sources or voltages. Resistor 312 of the circuit shown in FIG. 3 may be removed for the circuit in FIG. 7.

A charge pump 104, as shown in the embodiment of FIG. 3, may not be necessary for the circuit shown in FIG. 7 as a positive voltages Vgs1, Vgs2 smaller than VS and Vbat may render the N-channel first transistor T1 and the second transistor T2 conducting.

The regulating circuit 302 may be configured to regulate the potential of the second controlled terminal (or drain) D of the second transistor T2 to have the same potential as the potential of the second controlled terminal (or drain) D of the first transistor T1. A first input 306, for example a positive input, of the operational amplifier 304 may be coupled to the second controlled terminal D of the first transistor T1. A second input 308, for example a negative input, of the operational amplifier 304 may be coupled to the second controlled terminal D of the second transistor T2. The third transistor T3 of the regulating circuit 302 may be an N-channel transistor. It may have a first controlled terminal S (or source) coupled (or connected) to the second controlled terminal D of the second transistor T2. The second controlled terminal D (or drain) of the third transistor T3 may be coupled to the second supply voltage VS, for example via the detecting circuit 102, for example via the sense resistor 106.

In another embodiment, a P-channel transistor may be used instead of the N-channel transistor for the third transistor T3. A first input 306, for example a positive input, of the operational amplifier 304 may be coupled to the second controlled terminal D of the second transistor T2. A second input 308, for example a negative input, of the operational amplifier 304 may be coupled to the second controlled terminal D of the first transistor T1. In both embodiments, the detecting circuit 102 may be coupled to the second controlled terminal D of the second transistor T2 and will not cause the voltages Vgs1 and Vgs2 to differ from each other.

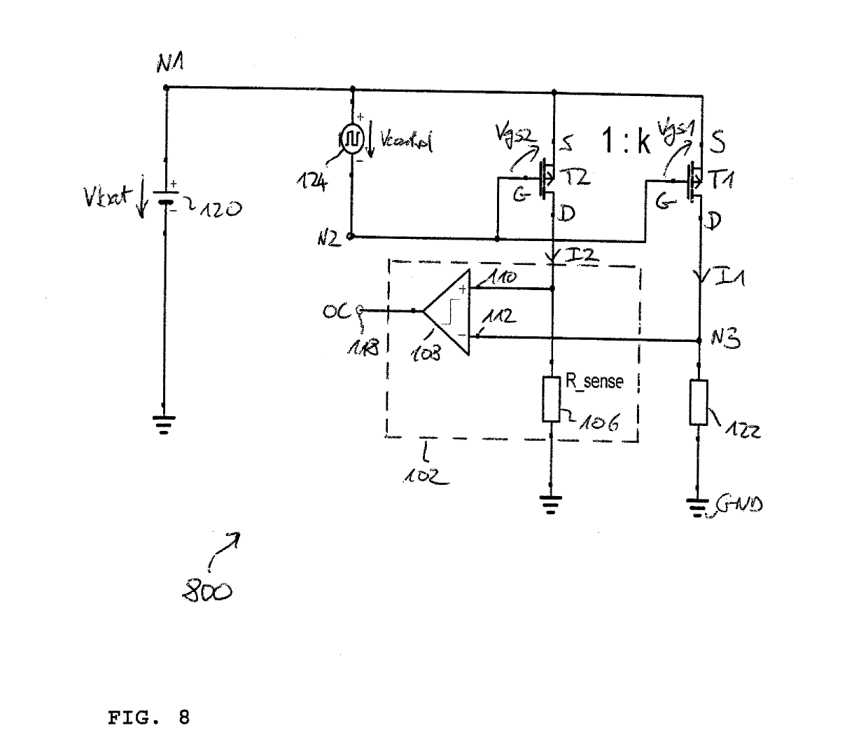

FIG. 8 shows an embodiment 800 of a circuit, which may be similar to the circuit described in conjunction with FIG. 6, so that the features described in conjunction with FIG. 6 may also apply to the circuit in FIG. 8.

The circuit shown in FIG. 8 may have opposite polarities to the polarities of the circuit shown in FIG. 6. In other words, an N-channel transistor may be replaced with a P-channel transistor and vice versa, a positive polarity may be replaced with a negative polarity and vice versa. In contrast to the circuit shown in FIG. 6, where the first transistor T1 and the second transistor T2 are configured as a low-side switches, the first transistor T1 and the second transistor T2 in FIG. 8 may be configured as a high-side switches. Further, they may be P-channel transistors instead of N-channel transistors. The first controlled terminals S (for example sources) of the first transistor T1 and of the second transistor T2 may both be coupled to the supply potential Vbat. The load 122 may be coupled between the first reference potential GND, for example a ground potential, and the second controlled terminal D (for example drain) of the first transistor T1. The sense resistor 106 may be coupled between the first reference potential GND and the second controlled terminal D (for example drain) of the second transistor T2.

A charge pump may again not be necessary. Signal Vcontrol may be configured to control the respective conductivity between the first controlled terminals S and the second controlled terminals D. It may be referenced at the supply potential Vbat and may provide a voltages Vgs1, Vgs2 negative with respect to the first controlled terminals S to render the P-channel first transistor T1 and the second transistor T2 conducting.

A first input 110 of the comparator 108, for example a positive input, may be coupled to the terminal of the sense resistor 106 that is not coupled to the first reference potential GND. A second input 112 of the comparator 108, for example a negative input, may be coupled to the terminal of the load 122 that is not coupled to the first reference potential GND. The potential difference between the first input 110 and the second input 112 may be given by I2·R_sense-I1 ·R_load. It may be positive if current I2 is larger than a certain value of current I1 and may be negative if current I2 is smaller than a certain value of current I1. Again, the detecting circuit 102 may be coupled to the second controlled terminal D of the second transistor T2 and will not cause the voltages Vgs1 and Vgs2 to differ from each other.

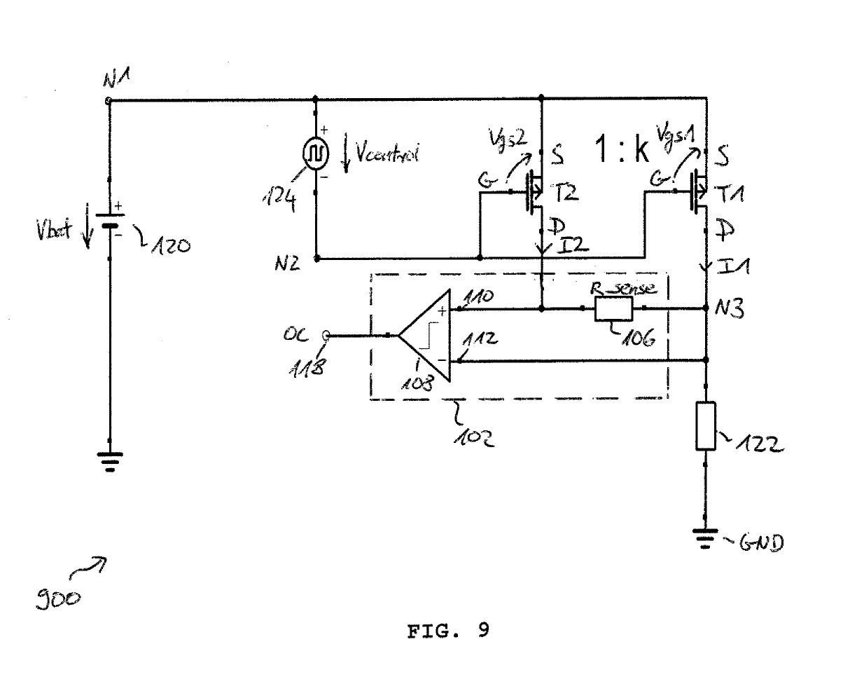

FIG. 9 shows an embodiment 900 of a circuit, which may be similar to the circuit described in conjunction with FIG. 8, so that the features described in conjunction with FIG. 8 may also apply to the circuit in FIG. 9.

In contrast to the circuit shown in FIG. 8, where the sense resistor 106 may be coupled between the second controlled terminal D of the second transistor T2 and the first reference potential GND, the sense resistor 106 in FIG. 9 may be coupled between the second controlled terminal D of the second transistor T2 and the second controlled terminal D of the first transistor T1.

The current I2 flowing through the sense resistor 106 may flow together with the current I1 through the load 122. No current is lost due to sensing using the second transistor T2, which may increase the efficiency of the circuit. The sense resistor 106 may be an internal resistor. An external sense resistor may be optional.

The potential difference between the first input 110 and the second input 112 of the comparator 108 may be given by I2·R_sense. Again, the detection circuit 102 may be coupled to the second controlled terminal D of the second transistor T2 and will not influence the voltage Vgs1 and Vgs2.

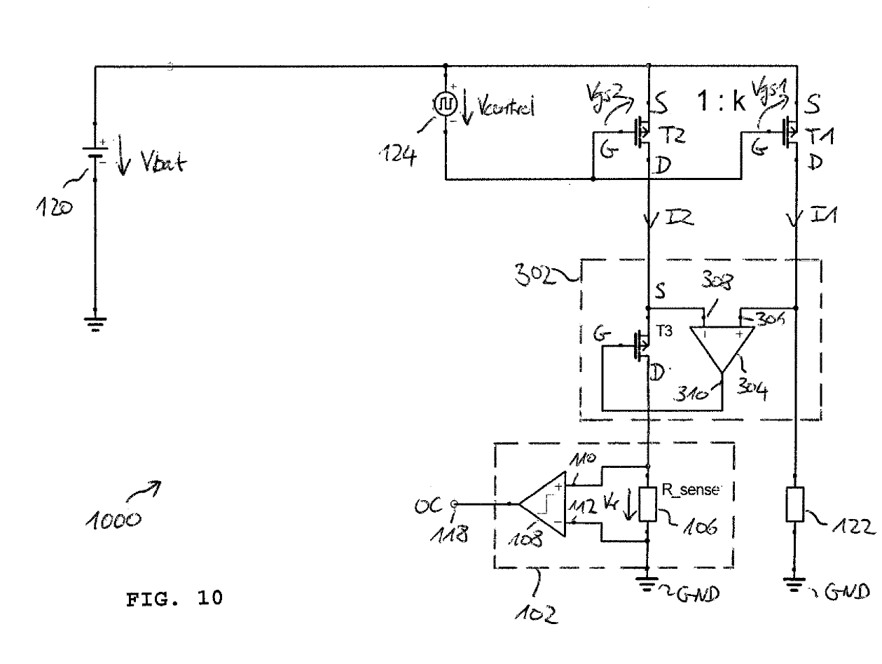

FIG. 10 shows an embodiment 1000 of a circuit, which may be similar to the circuit described in conjunction with FIG. 7, so that the features described in conjunction with FIG. 7 may also apply to the circuit in FIG. 10.

The circuit shown in FIG. 10 may have opposite polarities to the polarities of the circuit shown in FIG. 7. In other words, an N-channel transistor may be replaced with a P-channel transistor and vice versa, a positive polarity may be replaced with a negative polarity and vice versa. In contrast to the circuit shown in FIG. 7, where the first transistor T1 and the second transistor T2 are configured as a low-side switches, the first transistor T1 and the second transistor T2 in FIG. 10 may be configured as a high-side switches. The N-channel first transistor T1 coupled to ground GND (low side switch) in FIG. 7 may become a P-channel first transistor T1 coupled to a supply potential Vbat (high side switch) in FIG. 10. Signal Vcontrol becomes a negative voltage with respect to the supply potential Vbat. The N-channel third transistor T3 in FIG. 7 becomes a P-channel third transistor T3 in FIG. 10. The detection circuit 102 coupled to the supply potential VS in FIG. 7 is coupled to the first reference potential GND in FIG. 10.

Like in the other high side P-channel circuits shown in FIGS. 8 and 9, the signal controlling the conductivity between the first controlled terminal S and the second controlled terminal D, for example Vgs1, Vgs2 remains unaffected by the current detection. While FIG. 10 shows the load 122 and the sense resistor 106 coupled to the same first reference potential GND, they may also be coupled to different reference potentials, similar to the different supply potentials VS and Vbat shown in FIG. 7.

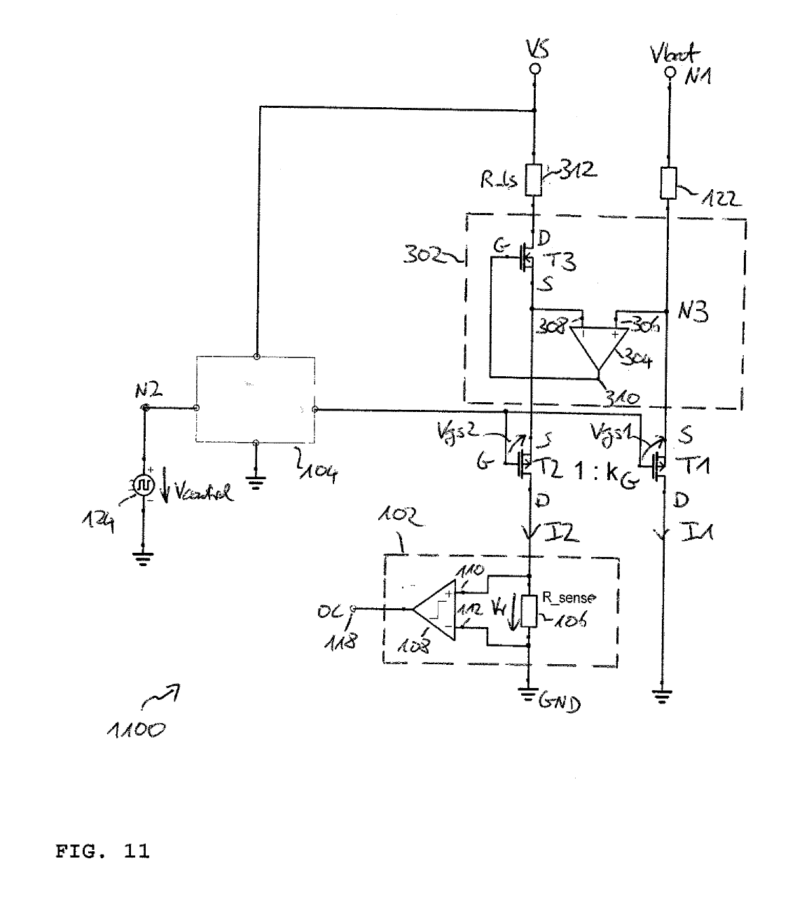

FIG. 11 shows an embodiment 1100 of a circuit, which may be similar to the circuit described in conjunction with FIG. 3, so that the features described in conjunction with FIG. 3 may also apply to the circuit in FIG. 11.

The circuit shown in FIG. 11 may have opposite polarities to the polarities of the circuit shown in FIG. 3. In other words, an N-channel transistor may be replaced with a P-channel transistor and vice versa, and a positive polarity may be replaced with a negative polarity and vice versa. In contrast to the circuit shown in FIG. 3, where the first transistor T1 and the second transistor T2 are configured as a low-side switches, the first transistor T1 and the second transistor T2 in FIG. 11 may be configured as a high-side switches. For example, the second controlled terminal D of the N-channel first transistor T1 coupled to supply potential Vbat (high side switch) in FIG. 3 becomes the second controlled terminal D of a P-channel first transistor Ti coupled to ground (low side switch) in FIG. 11. The P-channel third transistor T3 in FIG. 3 becomes a N-channel third transistor T3 in FIG. 11. In FIG. 11, the level shifter (or charge pump) 104 may convert signal Vcontrol to a voltage negative with respect to the potentials of the first controlled terminals S instead of converting it to a voltage positive with respect to the first reference potential GND as in FIG. 3. The load 122 and the sense resistor 102 may be coupled to different supply potentials, for example VS and Vbat. However, they may also be coupled to the same second supply potential. The sense resistor 106 in FIG. 11 is now coupled between the second controlled terminal D of the second transistor T2 and the first reference potential GND, instead of being coupled between the second controlled terminal D and the supply potential Vbat, as in FIG. 3. Resistor 312 may again provide a path for current I2 through the second transistor T2.

The signals controlling the respective conductivity between the respective first controlled terminal S and the respective second controlled terminal D, for example Vgs1 and Vgs2, remain unaffected by the current detection.

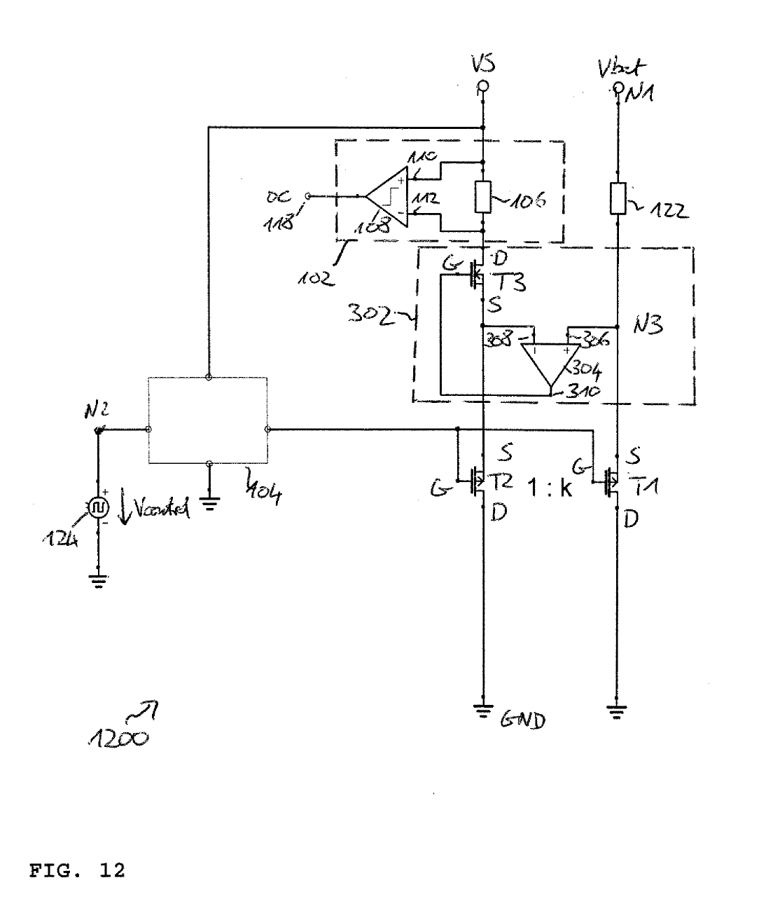

FIG. 12 shows an embodiment 1200 of a circuit, which may be similar to the circuit described in conjunction with FIG. 11, so that the features described in conjunction with FIG. 11 may also apply to the circuit in FIG. 12.

In contrast to the circuit shown in FIG. 11, there is no resistor coupled between the second controlled terminal D of the second transistor T2 and the first reference potential GND. Instead, the second controlled terminal D of the second transistor T2 is directly connected to the first reference potential GND. The comparator 108 is coupled across a resistor coupled between the supply potential Vs and the second controlled terminal D of the third transistor T3.

The circuit shown in FIG. 11 may also be similar to the circuit described in conjunction with FIG. 7, so that the features described in conjunction with FIG. 7 may also apply to the circuit in FIG. 12. In contrast to the circuit shown in FIG. 7, where the first transistor T1 and the second transistor T2 are N-channel transistors, the first transistor (or power transistor) T1 and the second transistor (or sense transistor) T2 in FIG. 12 may be P-channel transistors. A level shifter 104 or charge pump may be needed to provide voltages Vgs1 and Vgs2 negative with respect to the first controlled terminal S to render the P-channel first transistor T1 and the second transistor T2 conducting. Again, the signal controlling the conductivity of between the first controlled terminal S and the second controlled terminal D, for example Vgs1 and Vgs2, may remain unaffected by the current detection as the source potentials of the first transistor T1 and the second transistor T2 are regulated to have the same value by the regulator circuit 302.

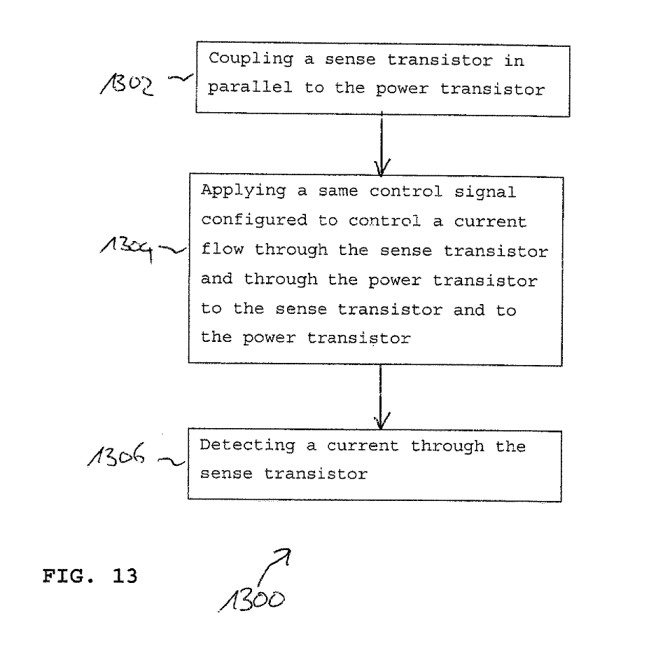

FIG. 13 shows an embodiment 1300 of a method for measuring a current, for example through a transistor, for example through a power transistor. The method may include steps 1302, 1304 and 1306.

In step 1302, a sense transistor may be coupled in parallel to a power transistor.

In step 1304, a same control signal may be applied to the sense transistor and to the power transistor. The same control signal may be configured to control a current flow through the sense transistor and to control a current flow through the power transistor. In various embodiments, applying the same control signal to the sense transistor and to the power transistor may include applying a same first potential, for example a gate potential, to a first control terminal, for example gate, of the sense transistor and to a first control terminal, a gate, of the power transistor, and setting a first controlled terminal, for example a source, of the sense transistor and a first controlled terminal, for example a source, of the power transistor to have a same second potential, for example a source potential.

In step 1306, a current through the sense transistor may be detected. In various embodiments, detecting the current through the sense transistor may include detecting a voltage across a sense resistor coupled to a second controlled terminal or drain of the sense transistor. In various embodiments, the method may further include coupling a supply input of a detection circuit to a non-floating or fixed voltage. The non-floating or fixed voltage may be a supply voltage, for example for the load, the sense transistor or the power transistor, for example Vbat or VS, which is referenced to another potential, for example a ground potential GND.

In various embodiments, the method may further include manufacturing a power transistor and a sense transistor on a same semiconductor substrate with a second controlled terminal (or drain) of the power transistor being separate or electrically isolated from a second controlled terminal (or drain) of the sense transistor.

While the invention has been particularly shown and described with reference to specific embodiments, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

Alternately and/or additionally, the scope of the disclosure is specifically intended to include without limitation at least the embodiments described in the enumerated clauses below. Equivalents thereof are also explicitly embraced.

1. A circuit, configured to provide a current from a supply voltage to a load, comprising:

a first transistor;

a second transistor; and

a detecting circuit configured to detect a current through the second transistor;

wherein the first transistor has a larger active area than the second transistor;

wherein a same voltage is applied between a control terminal of the first transistor and a first controlled terminal of the first transistor and is applied between a control terminal of the second transistor and a first controlled terminal of the second transistor;

wherein the detecting circuit is coupled to the second controlled terminal of the second transistor; and

wherein the detecting circuit is coupled to the supply voltage.

2. The circuit of claim 1, wherein

the first transistor and the second transistor are both one of:
metal oxide semiconductor field effect transistors, wherein the control terminals are gate terminals, the first controlled terminals are source terminals, and the second controlled terminals are drain terminals; and
insulated gate bipolar transistors, wherein the control terminals are gate terminals, the first controlled terminals are emitter terminals, and the second controlled terminals are collector terminals.
   3. The circuit of clause 1 or 2, wherein

the first transistor and the second transistor are one of:
vertical common source transistors integrated on a common substrate; wherein the first transistor and the second transistor have separate drain electrodes; and
vertical common emitter transistors integrated on a common substrate; wherein the first transistor and the second transistor have separate collector electrodes.
   4. The circuit of one of clauses 1 to 3, wherein

the first transistor and the second transistor are:
source-down transistors in case of vertical common source transistors; and
emitter-down transistors in case of vertical common emitter transistors.
   5. The circuit of one of clauses 1 to 4, further comprising:

a regulator circuit configured to set one of:
the first controlled terminal of the first transistor and the first controlled terminal of the second transistor to have a same potential; and
the second controlled terminal of the first transistor and the second controlled terminal of the second transistor to have a same potential.
   6. The circuit of clause 5, wherein

the regulator circuit comprises an operational amplifier and a third transistor; wherein
an output of the operational amplifier is coupled to a control terminal of the third transistor;
in case that the regulator circuit is configured to set the first controlled terminal of the first transistor and the first controlled terminal of the second transistor to have a same potential, a first controlled terminal of the third transistor is coupled to the first controlled terminal of the second transistor; and an input of the operational amplifier is coupled between the first controlled terminal of the first transistor and the first controlled terminal of the second transistor; and
in case that the regulator circuit is configured to set the second controlled terminal of the first transistor and the second controlled terminal of the second transistor to have a same potential, a first controlled terminal of the third transistor is coupled to the second controlled terminal of the second transistor; and an input of the operational amplifier is coupled between the second controlled terminal of the first transistor and the second controlled terminal of the second transistor.
   7. The circuit of clause 6, further comprising at least one of:

a resistor coupled to the first controlled terminal of the third transistor; and

a fourth transistor with a level shifter, wherein a second controlled terminal of the fourth transistor is coupled to the second controlled terminal of the third transistor, and a control terminal of the fourth transistor is coupled to the control terminal of the third transistor via the level shifter.

8. The circuit of one of clauses 1 to 7, wherein

the detecting circuit comprises a resistor coupled between one of:

a ground potential and the second controlled terminal of the second transistor;

a supply potential and the second controlled terminal of the second transistor; and

the second controlled terminal of the first transistor and the second controlled terminal of the second transistor.

9. The circuit of clause 8, wherein

the detecting circuit further comprises a comparator coupled across the resistor, wherein the comparator is connected to the supply voltage.

10. The circuit of clause 8, wherein

the second controlled terminal of the first transistor and the second controlled terminal of the second transistor are coupled to a common supply potential; and

the comparator is powered by the common supply potential.

11. The circuit of clause 8, wherein

the second controlled terminal of the first transistor is coupled to a first supply potential; the second controlled terminal of the second transistor is coupled to a second supply potential; and

the comparator is powered by the second supply potential.

12. A switch with over-current protection, comprising:

a power transistor;

a sense transistor;

a sense resistor; and

an over-current detection circuit,

wherein the power transistor and the sense transistor are integrated on a common substrate as source-down transistors with respective drains;

wherein the sense resistor is coupled to a drain terminal of the sense transistor; and

wherein the over-current detection circuit is configured to detect a voltage drop across the sense resistor.

13. The switch of clause 12, wherein

a gate of the power transistor and a gate of the sense transistor are coupled together; and

a source of the power transistor and a source of the sense transistor are configured to be at the same potential.

14. The switch of clause 12 or 13, wherein the drain terminal of the sense transistor and the over-current detection circuit are connected to a same supply potential.
15. The switch of one of clauses 12 to 14, wherein

the drain of the power transistor is isolated in the substrate from the drain of the sense transistor.

16. A method for measuring a current through a power transistor configured to provide a current from a supply voltage to a load, comprising:

coupling a sense transistor in parallel to the power transistor;

applying a same control signal to the sense transistor and to the power transistor, wherein the same control signal is configured to control a current flow through the sense transistor and to control a current flow through the power transistor; and

detecting a current through the sense transistor.

17. The method of clause 16, wherein

applying the same control signal to the sense transistor and to the power transistor comprises:

applying a first same potential to a control terminal of the sense transistor and to a control terminal of the power transistor, and

setting a first controlled terminal of the sense transistor and a first controlled terminal of the power transistor to have a second same potential.

18. The method of clause 16 or 17, wherein

detecting the current through the sense transistor comprises:

detecting a voltage across a sense resistor coupled to a second controlled terminal of the sense transistor.

19. The method of one of clauses 16 to 18, further comprising:

supplying a detecting circuit configured to detect the current through the sense transistor with the supply voltage..

20. The method of one of clauses 16 to 19, further comprising:

manufacturing the power transistor and the sense transistor on a common semiconductor substrate, wherein a second controlled terminal of the power transistor is separate from a second controlled terminal of the sense transistor.

What is claimed is:

1. A circuit, configured to provide a current from a supply voltage to a load, comprising:
a first transistor;
a second transistor; and
a detecting circuit configured to detect a current through the second transistor;
wherein the first transistor has a larger active area than the second transistor;
wherein a same voltage is applied between a control terminal of the first transistor and a first controlled terminal of the first transistor and is applied between a control terminal of the second transistor and a first controlled terminal of the second transistor;
wherein the detecting circuit is coupled to the second controlled terminal of the second transistor; and
wherein the detecting circuit is coupled to the supply voltage.

2. The circuit of claim 1, wherein
the first transistor and the second transistor are both one of:
metal oxide semiconductor field effect transistors, wherein the control terminals are gate terminals, the first controlled terminals are source terminals, and the second controlled terminals are drain terminals; and
insulated gate bipolar transistors, wherein the control terminals are gate terminals, the first controlled terminals are emitter terminals, and the second controlled terminals are collector terminals.

3. The circuit of claim 1, wherein
the first transistor and the second transistor are one of:
vertical common source transistors integrated on a common substrate; wherein the first transistor and the second transistor have separate drain electrodes; and
vertical common emitter transistors integrated on a common substrate; wherein the first transistor and the second transistor have separate collector electrodes.

4. The circuit of claim 1, wherein
the first transistor and the second transistor are:
source-down transistors in case of vertical common source transistors; and
emitter-down transistors in case of vertical common emitter transistors.

5. The circuit of claim 1, further comprising:
a regulator circuit configured to set one of:
the first controlled terminal of the first transistor and the first controlled terminal of the second transistor to have a same potential; and
the second controlled terminal of the first transistor and the second controlled terminal of the second transistor to have a same potential.

6. The circuit of claim 5, wherein
the regulator circuit comprises an operational amplifier and a third transistor; wherein
an output of the operational amplifier is coupled to a control terminal of the third transistor;
in case that the regulator circuit is configured to set the first controlled terminal of the first transistor and the first controlled terminal of the second transistor to have a same potential, a first controlled terminal of the third transistor is coupled to the first controlled terminal of the second transistor; and an input of the operational amplifier is coupled between the first controlled terminal of the first transistor and the first controlled terminal of the second transistor; and
in case that the regulator circuit is configured to set the second controlled terminal of the first transistor and the second controlled terminal of the second transistor to have a same potential, a first controlled terminal of the third transistor is coupled to the second controlled terminal of the second transistor; and an input of the operational amplifier is coupled between the second controlled terminal of the first transistor and the second controlled terminal of the second transistor.

7. The circuit of claim 6, further comprising at least one of:
a resistor coupled to the first controlled terminal of the third transistor; and
a fourth transistor with a level shifter, wherein a second controlled terminal of the fourth transistor is coupled to the second controlled terminal of the third transistor, and a control terminal of the fourth transistor is coupled to the control terminal of the third transistor via the level shifter.

8. The circuit of claim 1, wherein
the detecting circuit comprises a resistor coupled between one of:
a ground potential and the second controlled terminal of the second transistor;
a supply potential and the second controlled terminal of the second transistor; and
the second controlled terminal of the first transistor and the second controlled terminal of the second transistor.

9. The circuit of claim 8, wherein
the detecting circuit further comprises a comparator coupled across the resistor, wherein the comparator is connected to the supply voltage.

10. The circuit of claim 8, wherein
the second controlled terminal of the first transistor and the second controlled terminal of the second transistor are coupled to a common supply potential; and
the comparator is powered by the common supply potential.

11. The circuit of claim 8, wherein
the second controlled terminal of the first transistor is coupled to a first supply potential;
the second controlled terminal of the second transistor is coupled to a second supply potential; and
the comparator is powered by the second supply potential.

12. A switch with over-current protection, comprising:
a power transistor;
a sense transistor;
a sense resistor; and
an over-current detection circuit,
wherein the power transistor and the sense transistor are integrated on a common substrate as source-down transistors with respective drains;
wherein the sense resistor is coupled to a drain terminal of the sense transistor; and
wherein the over-current detection circuit is configured to detect a voltage drop across the sense resistor.

13. The switch of claim 12, wherein
a gate of the power transistor and a gate of the sense transistor are coupled together; and
a source of the power transistor and a source of the sense transistor are configured to be at the same potential.

14. The switch of claim 12, wherein
the drain terminal of the sense transistor and the over-current detection circuit are connected to a same supply potential.

15. The switch of claim 12, wherein
the drain of the power transistor is isolated in the substrate from the drain of the sense transistor.

16. A method for measuring a current through a power transistor configured to provide a current from a supply voltage to a load, comprising:
coupling a sense transistor in parallel to the power transistor;
applying a same control signal to the sense transistor and to the power transistor, wherein the same control signal is configured to control a current flow through the sense transistor and to control a current flow through the power transistor; and
detecting a current through the sense transistor.

17. The method of claim 16, wherein
applying the same control signal to the sense transistor and to the power transistor comprises:
applying a first same potential to a control terminal of the sense transistor and to a control terminal of the power transistor, and
setting a first controlled terminal of the sense transistor and a first controlled terminal of the power transistor to have a second same potential.

18. The method of claim 16, wherein
detecting the current through the sense transistor comprises:
detecting a voltage across a sense resistor coupled to a second controlled terminal of the sense transistor.

19. The method of claim 16, further comprising:
supplying a detecting circuit configured to detect the current through the sense transistor with the supply voltage.

20. The method of claim 16, further comprising:
manufacturing the power transistor and the sense transistor on a common semiconductor substrate, wherein a second controlled terminal of the power transistor is separate from a second controlled terminal of the sense transistor.
